(19) United States
(12) Patent Application Publication
(10) Pub. No.: US 2009/0128235 A1
(43) Pub. Date: May 21, 2009

(54) Power save mode for audio interface drive amplifier

(75) Inventor: Ossi Ensio Maenpaa, Salo (FI)

Correspondence Address: HARRINGTON & SMITH, PC, 4 RESEARCH DRIVE, Suite 202, SHELTON, CT, 06484-6212, US

(73) Assignee: Nokia Corporation

(21) Appl. No.: 11/986,575

(22) Filed: Nov. 20, 2007

(51) Int. Cl. H03G 3/20

(52) U.S. Cl. 330/127

(57) ABSTRACT

An apparatus includes a data processor coupled with a memory that stores a program executable by the data processor; an accessory interface readably coupled with the data processor and an amplifier having an output coupled to the accessory interface and a program input coupled to the data processor. The amplifier is responsive to the program input to change a current consumption of the amplifier in accordance with at least one electrical characteristic associated with an accessory that is connected to the accessory interface. The data processor programs the amplifier to operate in a stable mode of operation while consuming as little current as needed to operate the amplifier in the stable mode of operation. The data processor directly or indirectly determines an amount of capacitance and/or impedance associated with an interface to the accessory, and programs the amplifier accordingly.

### TECHNICAL FIELD

The exemplary and non-limiting embodiments of this invention relate generally to communication systems, methods, devices and computer program products and, more specifically, relate to techniques to conserve operating power when using an audio amplifier, and generally to power management, audio circuitry and baseband hardware and software.

### BACKGROUND

A considerable proportion of an output accessory amplifier (e.g., audio amplifier) total current consumption during use is idle current. The idle current needs to be present in order to ensure that the amplifier remains stable with various output loads, including various capacitive loads. A typical load for an accessory audio amplifier is a headset that includes audio transducers enabling a user to listen to music and other audio content. While a typical headset may not present a large capacitive load to the audio amplifier, the wiring (audio cable) to the headset may. The headset also has a low impedance (typically 32 ohm). For amplifier oscillation a challenging situation is high capacitance and impedance at same time (such as a connection to a home stereo with long cables). To avoid oscillation in the case where a user connects a lengthy audio cable the audio amplifier my be designed to operate with a higher standby or idle mode current that is actually needed for most amplifier use cases. The provision of additional idle current to achieve amplifier stability or “stiffness” implies increased idle mode or quiescent power consumption, which is detrimental in a battery powered device.

### SUMMARY OF THE EXEMPLARY EMBODIMENTS

The foregoing and other problems are overcome, and other advantages are realized, in accordance with the non-limiting and exemplary embodiments of this invention.

In a first aspect thereof the exemplary embodiments of this invention provide a method that includes sensing at least one electrical characteristic of an accessory that is connected to a device; and setting a current consumption of an amplifier stage that is used to drive the accessory in accordance with the sensed at least one electrical characteristic so as to operate the amplifier stage in a stable mode of operation while consuming as little current as needed to operate the amplifier stage in the stable mode of operation.

In another aspect thereof the exemplary embodiments of this invention provide a computer readable memory medium that stores a program of computer readable instructions, where execution of the instructions results in operations that comprise sensing at least one electrical characteristic of an accessory that is connected to a device; and setting a current consumption of an amplifier stage that is used to drive the accessory in accordance with the sensed at least one electrical characteristic so as to operate the amplifier stage in a stable mode of operation while consuming as little current as needed to operate the amplifier stage in the stable mode of operation.

In another aspect thereof the exemplary embodiments of this invention provide an apparatus that comprises means for sensing at least one electrical characteristic of an accessory that is connected to an apparatus; and means for setting a current consumption of an amplifier stage that is used to drive the accessory in accordance with the sensed at least one electrical characteristic so as to operate the amplifier stage in a stable mode of operation while consuming as little current as needed to operate the amplifier stage in the stable mode of operation.

In a further aspect thereof the exemplary embodiments of this invention provide an apparatus that includes a data processor coupled with a memory that stores a program executable by the data processor; an accessory interface readably coupled with the data processor and an amplifier having an output coupled to the accessory interface and a program input coupled to the data processor. The amplifier is responsive to the program input to change a current consumption of the amplifier in accordance with at least one determined electrical characteristic of an accessory connected to the accessory interface.

### BRIEF DESCRIPTION OF THE DRAWINGS

The foregoing and other aspects of the teachings of this invention are made more evident in the following Detailed Description, when read in conjunction with the attached Drawing Figures, wherein:

FIG. 1 is a block diagram of a device constructed and operated in accordance with the exemplary embodiments of this invention.

FIG. 2 shows a table that associates accessory types with amplifier setting(s), and which may be stored in the memory shown in FIG. 1.

FIG. 3 is a logic flow diagram that is descriptive of a method, and the result of execution of computer program code, in accordance with the exemplary embodiments of this invention.

### DETAILED DESCRIPTION

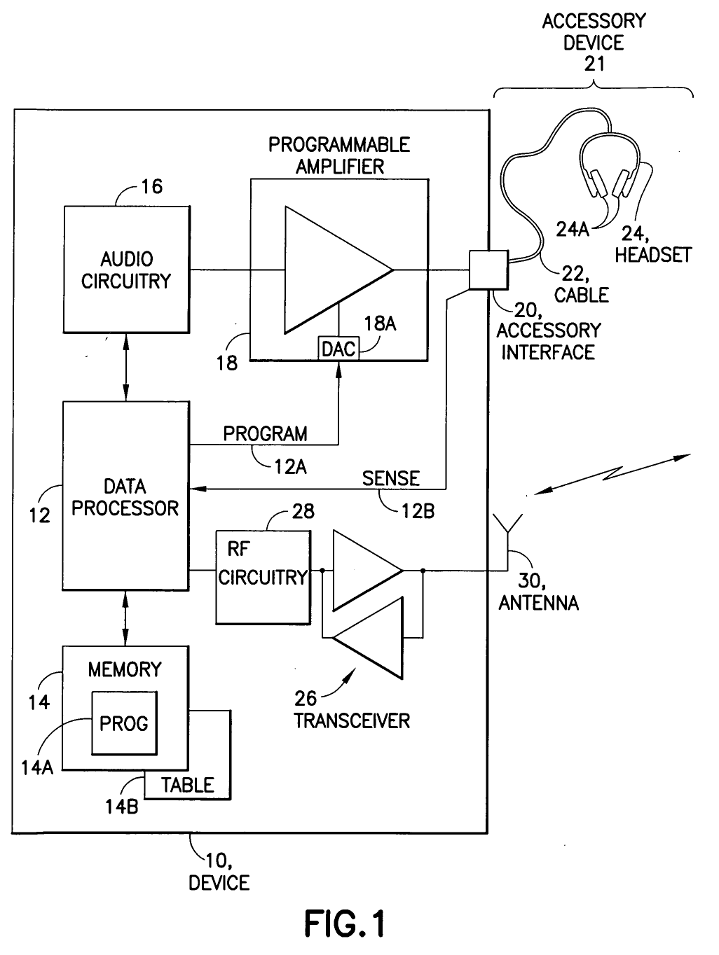

Reference is made to FIG. 1 for illustrating a simplified block diagram of an electronic device 10 that is suitable for use in practicing the exemplary embodiments of this invention. The device 10 includes a control unit, such as a microcontroller or data processor 12 that is coupled or connected with at least one memory 14. The memory 14 stores a program (PROG) 14A of computer program instructions for directing the operations of the data processor 12, including operations that implement the exemplary embodiments of this invention as described below. The device 10 also includes audio circuitry 16, such as at least one digital to analog converter (DAC) that outputs an analog waveform suitable for amplification and reproduction as music or and/or voice. To this end the device 10 includes an amplifier, embodied in the device as a programmable amplifier 18 (or amplifier stage, which may include additional active and/or passive components that support the operation of the amplifier per se). The output of the programmable amplifier 18 is connected with an accessory interface 20 to which a user of the device 10 may connect an accessory device 21. In one non-limiting example the accessory device 21 is a headset 24 that is connected via a cable 22. The headset 24 includes acoustic transducers 24A, such as miniature speakers, that enable the user to listen to the audio signal (e.g., music) output by the programmable amplifier 18.

In accordance with an aspect of this invention a program bus 12A is connected between the data processor 12 and the programmable amplifier 18 by which the data processor 12 is enabled to change at least one operating characteristic of the amplifier 18, preferably enabling at least an amount of idle current used by the amplifier 18 to be varied. In order to program the operation of the amplifier 18 it is assumed that the accessory interface 20 has an output, referred to herein as a sense output 12B, that is connected as an input to the data processor 12. By means of the sense output 12B the data processor 12 obtains knowledge of a type of accessory that is plugged into the accessory interface 20, and based on this knowledge can gain an indication of the characteristics of the accessory and thus an amount of amplifier 18 idle current that is actually required to operate the amplifier 18 in a stable mode.

Note that the device 10 may also include at least one wireless interface, such as a radio frequency (RF) transceiver 26 that is connected with RF circuitry 28 and at least one antenna 30. For example, the device 10 may be a cellular phone that includes music playback capability. Alternatively, the device 10 may be considered to be a music playback device that happens to include a wireless communications capability.

In general, the various embodiments of the device 10 can include, but are not limited to, cellular telephones, personal digital assistants (PDAs), portable computers, image capture devices such as digital cameras, gaming devices, music storage and playback appliances, Internet appliances, as well as portable units or devices that incorporate combinations of such functions.

The exemplary embodiments of this invention may be implemented by computer software executable by the data processor 12, or by hardware, or by a combination of software and hardware.

The memory 14 may be of any type suitable to the local technical environment and may be implemented using any suitable data storage technology, such as semiconductor-based memory devices, flash memory, magnetic memory devices and systems, optical memory devices and systems, fixed memory and removable memory. The data processor 12 may be of any type suitable to the local technical environment, and may include one or more of general purpose computers, special purpose computers, microprocessors, digital signal processors (DSPs) and processors based on a multi-core processor architecture, as non-limiting examples.

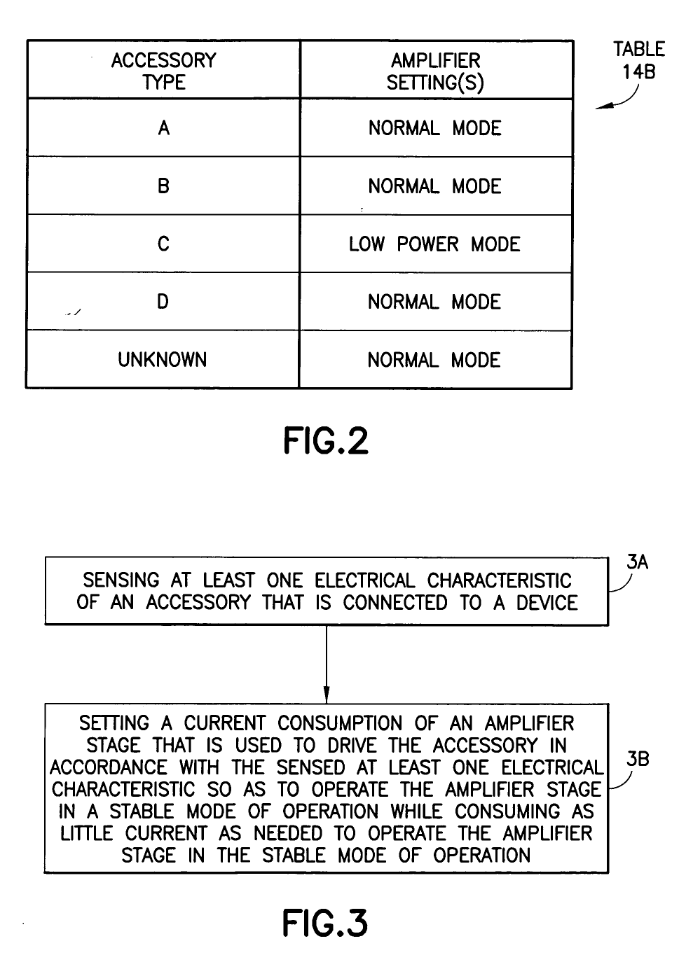

As a non-limiting example of the invention, the programmable amplifier 18 may be an integrated circuit (IC)-based amplifier with a programmably changeable topology suitable for driving different loads. Assuming that the data processor 12 gains knowledge of an amount of capacitance associated with the accessory, including the accessory wiring (cable 22), the data processor 12 is enabled to program the amplifier 18 via the programming bus 12A to set the amplifier 18 current mode to avoid unnecessary idle mode power consumption. For this purpose the memory 14 may also include a table 14B, shown also in FIG. 2, where the determined accessory type can be used to lookup the required setting(s) for the programmable amplifier 18. In this non-limiting example there are two modes of amplifier operation specified, a normal mode (high idle mode current) and low power mode (less idle mode current). In other embodiments there may be three or more amplifier settings specified (e.g., high, medium and low idle mode current). If the accessory type is not determinable by the data processor 12 from the sense output 12B, then the default amplifier setting may be the normal mode. The contents of the table 14B may be set in the factory or when the device 10 is purchased and initially configured. It is within the scope of the exemplary embodiments to change the contents of the table 14B during use, such as by over-the-air (OTA) programming via the wireless interface 26,28, of the device 10. In this manner new accessory types and their associated amplifier settings can be added to the table 14B and/or existing settings can be changed.

The sense output 12B can be implemented in any of a number of suitable manners. For example, plugging in the accessory 21 to the accessory interface 20 may place one or more interface pins into predetermined logic states that are readable by the data processor 12. Alternatively, an accessory server function of the device 10 may be capable of directly communicating with the accessory 21 to obtain accessory type information. Note that in this embodiment the table 14B may not be needed, as the accessory 21 may provide as part of the communication with the accessory server a suggested amplifier 18 setting for optimally driving the accessory 21. In this regard it is known that certain types of messages, such as gain messages, can be exchanged between a device accessory server and an accessory. It is also within the scope of these embodiments to place a small memory chip in the accessory 21 that contains at least an accessory identification, and that is readable by the data processor 12 when the accessory 21 is plugged in to the accessory interface 20, either through a dedicated communication signal line or lines, or through multiplexed signals sent over a common line, such as a speaker or microphone signal line.

It should be noted as well that the exemplary embodiments of this invention may be practiced by directly measuring or sensing the amplifier load capacitance with a plug detection functionality, and to then program the amplifier 18 appropriately. This can be especially useful if the accessory that is plugged in to the accessory interface 20 is not recognized. One non-limiting technique that may be used to accomplish this is to send a test pulse having predetermined characteristics, such as rise and fall times, to the cable 22 and to measure characteristics of a return or a reflected pulse to determine an amount of degradation experienced by the test pulse, which may be correlated at least in part with the amount of capacitance present in the cable 22. The impedance of the accessory interface 20 may be determined instead, or it may be determined in conjunction with determining the capacitance, by, as a non-limiting example, using a voltage divider technique. This approach is useful, since the audio output typically includes at least one series resistor (e.g., there may be a 16 ohm resistor in series in each of the audio left (L) and right (R) outputs).

In general, the accessory device 21 sensing function 21B carried out by the device 10 may comprise determining directly or indirectly an amount of capacitance associated with an interface to the accessory device 21 and/or determining directly or indirectly an amount of impedance associated with an interface to the accessory device 21. That is, the exemplary embodiments of this invention determine at least one electrical characteristic associated with the accessory device 21 and/or the interface to the accessory device 21 either directly, such as by sensing or measuring the at least one electrical characteristic, or indirectly such as by sensing or reading information that identifies the type of accessory device 21, and then correlating the identified type of accessory device 21 with the at least one electrical characteristic, such as by use of the table lookup procedure (table 14B).

The programmable amplifier 18 is assumed to have at least two operational modes with different characteristics:

a high current mode (normal, default) with a capability to drive capacitive loads; and

a low current mode (used only if accessory is recognized) with a lower stability margin, and less current consumption than the high current mode.

The amplifier 18 may be made programmable with regards to efficiency and power consumption by changing one or more amplifier bias current/voltage levels, and/or by switching in or out gain stages, and/or by switching in or out individual ones of paralleled output transistors, and/or by changing the value of the amplifier operating voltage, or by any technique that is capable of achieving operation with different levels of amplifier power consumption. More generally, setting (programming) the amplifier stage 18 comprises at least one of changing a physical topology of the amplifier stage and changing at least one electrical operating parameter (e.g., bias current/voltage value) of the amplifier stage.

In general, adjusting the bias current of the amplifier 18 may be the most preferred technique, as it can be done in a relatively straightforward manner, at least with respect to a class AB-type of amplifier. For example, and as is shown in FIG. 1, the programmable amplifier 18 may include a digital to analog converter (DAC) 18A having an analog output used for setting/adjusting an operating parameter of the amplifier 18, such as adjusting the amplifier bias current and/or voltage.

By setting the amplifier 18 to the low power mode the total current consumption may be reduced, for example, by approximately one half (e.g., from 5 mA to 2-3 mA). The lower power consumption mode is especially advantageous when the user listens to music for an extended period of time, as battery life (and music playback time) is extended.

Referring to FIG. 3, a method in accordance with the exemplary embodiments of this invention includes (Block 3A) sensing at least one electrical characteristic of an accessory that is connected to a device; and (Block 3B) setting a current consumption of an amplifier stage that is used to drive the accessory in accordance with the sensed at least one electrical characteristic so as to operate the amplifier stage in a stable mode of operation while consuming as little current as needed to operate the amplifier stage in the stable mode of operation.

The method as above, where sensing comprises determining directly or indirectly at least one of an amount of capacitance and impedance associated with an interface to the accessory device.

The method as above, where if sensing does not determine the at least one electrical characteristic, then the current consumption of the amplifier stage is set so as not to reduce the current consumption from a normal, default value of current consumption.

The method as above, where setting comprises at least one of changing a physical topology of the amplifier stage and changing at least one electrical operating parameter of the amplifier stage.

The various blocks shown in FIG. 3 may be viewed as method steps, and/or as operations that result from operation of computer program code (e.g., the program 14A stored in the memory 14), and/or as a plurality of coupled logic circuit elements constructed to carry out the associated function(s).

In general, the various exemplary embodiments may be implemented in hardware or special purpose circuits, software, logic or any combination thereof. For example, some aspects may be implemented in hardware, while other aspects may be implemented in firmware or software which may be executed by a controller, microprocessor or other computing device, although the invention is not limited thereto. While various aspects of the exemplary embodiments of this invention may be illustrated and described as block diagrams, flow charts, or using some other pictorial representation, it is well understood that these blocks, apparatus, systems, techniques or methods described herein may be implemented in, as non-limiting examples, hardware, software, firmware, special purpose circuits or logic, general purpose hardware or controller or other computing devices, or some combination thereof.

As such, it should be appreciated that at least some aspects of the exemplary embodiments of the inventions may be practiced in various components such as integrated circuit chips and modules. For example, certain aspects of this invention may be practiced in a baseband section of an integrated circuit designed to operate in a wireless communications device. The design of integrated circuits is by and large a highly automated process. Complex and powerful software tools are available for converting a logic level design into a semiconductor circuit design ready to be fabricated on a semiconductor substrate. Such software tools can automatically route conductors and locate components on a semiconductor substrate using well established rules of design, as well as libraries of pre-stored design modules. Once the design for a semiconductor circuit has been completed, the resultant design, in a standardized electronic format (e.g., Opus, GDSII, or the like) may be transmitted to a semiconductor fabrication facility for fabrication as one or more integrated circuit devices.

Various modifications and adaptations may become apparent to those skilled in the relevant arts in view of the foregoing description, when read in conjunction with the accompanying drawings and the appended claims. However, any such modifications of the exemplary embodiments of this invention will still fall within the scope of this invention.

It should be noted that the terms “connected,” “coupled,” or any variant thereof, mean any connection or coupling, either direct or indirect, between two or more elements, and may encompass the presence of one or more intermediate elements between two elements that are “connected” or “coupled” together. The coupling or connection between the elements can be physical, logical, or a combination thereof. As employed herein two elements may be considered to be “connected” or “coupled” together by the use of one or more wires, cables and/or printed electrical connections, as well as by the use of electromagnetic energy, such as electromagnetic energy having wavelengths in the radio frequency region, the microwave region and the optical (both visible and invisible) region, as several non-limiting and non-exhaustive examples.

Furthermore, some of the features of the examples of this invention may be used to advantage without the corresponding use of other features. As such, the foregoing description should be considered as merely illustrative of the principles, teachings, examples and exemplary embodiments of this invention, and not in limitation thereof.

What is claimed is:

1. A method comprising:
sensing at least one electrical characteristic of an accessory that is connected to a device; and
setting a current consumption of an amplifier stage that is used to drive the accessory in accordance with the sensed at least one electrical characteristic so as to operate the amplifier stage in a stable mode of operation while consuming as little current as needed to operate the amplifier stage in the stable mode of operation.

2. The method of claim 1, where sensing comprises determining directly or indirectly at least one of an amount of capacitance and impedance associated with an interface to the accessory.

3. The method of claim 1, where if sensing does not determine the at least one electrical characteristic, then the current consumption of the amplifier stage is set so as not to reduce the current consumption from a normal, default value of current consumption.

4. The method of claim 1, where setting comprises at least one of changing a physical topology of the amplifier stage and changing at least one electrical operating parameter of the amplifier stage.

5. A computer readable memory medium that stores a program of computer readable instructions, execution of the instructions resulting in operations that comprise:
sensing at least one electrical characteristic of an accessory that is connected to a device; and
setting a current consumption of an amplifier stage that is used to drive the accessory in accordance with the sensed at least one electrical characteristic so as to operate the amplifier stage in a stable mode of operation while consuming as little current as needed to operate the amplifier stage in the stable mode of operation.

6. The computer readable memory medium of claim 5, where sensing comprises determining directly or indirectly at least one of an amount of capacitance and impedance associated with an interface to the accessory.

7. The computer readable memory medium of claim 5, where if sensing does not determine the at least one electrical characteristic, then the current consumption of the amplifier stage is set so as not to reduce the current consumption from a normal, default value of current consumption.

8. The computer readable memory medium of claim 5, where setting comprises at least one of changing a physical topology of the amplifier stage and changing at least one electrical operating parameter of the amplifier stage.

9. An apparatus, comprising:
means for sensing at least one electrical characteristic of an accessory that is connected to an apparatus; and
means for setting a current consumption of an amplifier stage that is used to drive the accessory in accordance with the sensed at least one electrical characteristic so as to operate the amplifier stage in a stable mode of operation while consuming as little current as needed to operate the amplifier stage in the stable mode of operation.

10. The apparatus of claim 9, where said sensing means comprises means for determining directly or indirectly at least one of an amount of capacitance and impedance associated with an interface to the accessory.

11. The apparatus of claim 9, where if said sensing means does not determine the at least one electrical characteristic, then said setting means sets the current consumption of the amplifier stage so as not to reduce the current consumption from a normal, default value of current consumption.

12. The apparatus of claim 9, where said sensing means is configurable for at least one of changing a physical topology of the amplifier stage and changing at least one electrical operating parameter of the amplifier stage.

13. An apparatus, comprising:
a data processor coupled with a memory that stores a program executable by the data processor;
an accessory interface readably coupled with the data processor; and
an amplifier having an output coupled to the accessory interface and a program input coupled to the data processor, said amplifier responsive to the program input to change a current consumption of said amplifier in accordance with at least one determined electrical characteristic of an accessory connected to the accessory interface.

14. The apparatus of claim 13, where said data processor programs the amplifier to operate in a stable mode of operation while consuming as little current as needed to operate the amplifier in the stable mode of operation.

15. The apparatus of claim 13, where said data processor directly or indirectly determines at least one of an amount of capacitance and impedance associated with an interface to the accessory.

16. The apparatus of claim 13, where if said data processor does not determine the at least one electrical characteristic, then the current consumption of the amplifier is set so as not to reduce the current consumption from a normal, default value of current consumption.

17. The apparatus of claim 13, where said amplifier is responsive to the program input to change at least one of a physical topology of the amplifier and at least one electrical operating parameter of the amplifier.

18. The apparatus of claim 13, where said amplifier is an audio amplifier, and where the accessory comprises a user headset connectable to the accessory interface via a cable having a characteristic capacitance.

19. The apparatus of claim 13, further comprising a wireless communication interface.

20. The apparatus of claim 13, embodied as a wireless communication device having music playback capability to a headset accessory that is connectable to the accessory interface.

21. The apparatus of claim 13, embodied at least partially as an integrated circuit.

22. The apparatus of claim 13, embodied at least partially as a baseband integrated circuit of a wireless communications device.

23. The apparatus of claim 13, where the program input adjusts at least one of a bias current and voltage to the amplifier.

24. The apparatus of claim 13, where the at least one electrical characteristic is determined by measurement.

25. The apparatus of claim 13, where the at least one electrical characteristic is determined by sensing a type of accessory, and correlating the type of accessory with the at least one electrical characteristic.
